(19) United States
(12) Patent Application Publication
(10) Pub. No.: US 2007/0221939 A1
(43) Pub. Date: Sep. 27, 2007

(54) Optically reliable nanoparticle based nanocomposite HRI encapsulant, photonic waveguiding material and high electric breakdown field strength insulator/encapsulant

(75) Inventors: Nikhil R. Taskar, Scarsdale, NY (US); Vishal Chhabra, Ossining, NY (US); Aleksey Yekimov, White Plains, NY (US); Donald Dorman, Carmel, NY (US); Bharati S. Kulkarni, Cortlandt Manor, NY (US)

Correspondence Address: William L. Botjer, Box 478, Center Morlches, NY, 11934, US

(73) Assignee: NANOCRYSTAL LIGHTING CORPORATION

(21) Appl. No.: 11/803,268

(22) Filed: May 14, 2007

Related U.S. Application Data
(63) Continuation-in-part of application No. PCT/US05/40991, filed on Nov. 14, 2005.
(60) Provisional application No. 60/628,239, filed on Nov. 16, 2004.

(51) Int. Cl. H01L 33/00

(52) U.S. Cl. 257/98

(57) ABSTRACT

An optically reliable high refractive index (HRI) encapsulant for use with Light Emitting Diodes (LED's) and lighting devices based thereon. This material may be used for optically reliable HRI lightguiding core material for polymer-based photonic waveguides for use in photonic-communication and optical-interconnect applications. The encapsulant includes treated nanoparticles coated with an organic functional group that are dispersed in an Epoxy resin or Silicone polymer, exhibiting RI˜1.7 or greater with a low value of optical absorption coefficient α<0.5 cm−1 at 525 nm. The encapsulant makes use of compositionally modified TiO₂ nanoparticles which impart a greater photodegradation resistance to the HRI encapsulant.

### REFERENCE TO RELATED APPLICATIONS

This application is a continuation in part of PCT application No. PCT/US2005/040991 which in turn claims priority of U.S. Provisional application Ser. No. 60/628239 filed Nov. 16, 2004.

### BACKGROUND AND SUMMARY OF THE INVENTION

This invention relates generally to solid state lighting applications and specifically to an optically reliable high refractive index (HRI) encapsulant for use with Light Emitting Diodes (LED's) and lighting devices based thereon. This invention also relates to optically reliable HRI lightguiding core material for polymer-based photonic waveguides for use in photonic-communication, optical-interconnect and display-lightguide applications. This invention also relates to an high electric breakdown field strength insulator and encapsulant for use in electrical/electronic device packaging applications.

Because of their energy efficiency, LED's have recently been proposed for lighting applications, particularly for specialty lighting applications, where energy inefficient incandescent and halogen lights are the norm. To date, three main approaches have been taken to provide so called “white” light from LED's. The first approach uses clusters of red, green and blue (RGB) LED's, with color mixing secondary-optics, to produce white light. This approach does provide good quality white light with a “color rendering index” (CRI) of ˜85 and is energy efficient, however, the need to drive three separate sets of LED's requires complex and more expensive driver circuitry. The complexity arises due to considerably different extent of degradation in efficiency with increasing temperature, for each of the red, green and blue LEDs and to different degradation lifetimes between the red, green and blue LEDs. Furthermore, high-brightness (5 mW to 1000 mW LED lamp) blue and green LED's have only recently been developed and are expensive when compared to red LED's.

A second approach to the generation of white light by LED's is the use of a high-brightness blue LED (450 nm to 470 nm) to energize a yellow phosphor, such as Yttrium aluminum garnet doped with cerium (YAIG:Ce called “YAG”). While this approach is energy efficient, low cost and manufacturable, it provides a lower quality white light with color temperature (CT) of ˜7000 K and CRI of ˜70 to 75, which is not acceptable for many high quality applications. The use of a thicker phosphor layer to absorb and down-convert more of the blue emission, can lower the color temperature and thereby improve the quality of white light. However, this results in a lower energy efficiency. Alternately, using a single or multiple phosphors with red emission in addition to yellowish-green (or greenish-yellow) emission can increase the color rendering index and thereby improve the quality of white light yielding a CT of ˜3000K and CRI of ˜80 to 85 but with lower energy efficiency. However, optical efficiency of the phosphor containing package is only about 50% to 60%, resulting in decreased light extraction in each of the above cases.

A third approach to the generation of white light by LED's is the use of a high-brightness UV/violet LED (emitting 370-430 nm radiation) to energize RGB phosphors. This approach provides high quality white light with CRI of ˜90 or higher, is low cost and is reliable to the extent that the encapsulant in the package, containing/surrounding the phosphor and LED chip/die does not degrade in the presence of UV/violet emission . This is due to shorter degradation lifetimes and a larger decrease in efficiency with increasing ambient temperature, for red LED chips compared to UV/violet or blue LED chips, which leads to greater color-maintenance problems and requires more complex driver circuitry. However, at present this approach has very poor efficiency because of the poor light conversion efficiency of the UV/violet excitable RGB phosphors currently in use. In addition, the optical efficiency of the phosphor containing package is only about 50% to 60%, resulting in a further decrease in light extraction.

The present invention is applicable to various modalities of LED/phosphor operation including: a blue LED with a yellowish (or RG) phosphor; RGB phosphors with a UV LED and deep UV LED with ‘white” fluorescent tube type phosphors and “white” lamps formed from clusters of red, green and blue LED's. The invention is also applicable to use with various sizes of phosphors: “bulk” micron sized phosphors, nanocrystalline phosphors (“nanophosphors”—less than 100 nm in average diameter and more preferably less than 40 nm)

Originally, LED's were operated in air, U.S. Pat. No. 3,877,052 (Dixon et.al,) issued in 1975 teaches the use of an optically transparent encapsulant surrounding the LED with a refractive index (RI) greater than that of air, to enhance the LED lamp light output emitted into the ambient. Since then, Epoxy-based encapsulants with RI˜1.5 have been the industry norm. LED lamps with RI˜1.5 encapsulant, exhibit light output that is typically 1.7× to 2.3× damping factor) times the light output from unencapsulated lamps, depending on details of the LED chip and lamp package.

The RI˜1.5 encapsulants have typically comprised of various chemistries, aromatic epoxy-anhydride cured, cycloaliphatic epoxy-anhydride cured or their combination, and epoxy-amine cured. Recent developments have also involved silicone-cycloaliphatic epoxy hybrid encapsulants and reactive-silicone based elastomer or gel encapsulants with RI˜1.5, that offer advantages from the standpoint of enhanced resistance to both thermally induced and optically induced discoloration at Blue/Violet/UV emission wavelengths.

Attempts to develop encapsulants with RI value greater than 1.6 based on ORMOCER (Organically Modified Ceramic) containing alloys of high refractive index oxides (such as for example, titanium oxide/bismuth oxide and silicon oxide) interspersed with polymer functional groups attached to the silicon containing molecule, have resulted in thin-films with RI˜2.0. But the attainment of thicknesses (on the order of 1 mm or larger) has proven to be problematic due to stress-related cracking that limits the film thickness to less than 100 microns. Also the high value of the optical absorption coefficient at green and blue wavelengths, limits the film thickness on the order of several tens of microns from the standpoint of attaining optical transparency.

Nanocomposite Ceramers based on high refractive index nanoparticles dispersed in organic matrices are described in U.S. Pat. No. 6,432,526, but exhibited compromised optical transparency despite attainment of RI values greater than 1.65 or 1.7. The present work has been able to attain higher optical transparency in Epoxy and both Reactive-Silicone and Nonreactive-Silicone based nanocomposite Ceramers, using a combination of a modified nanoparticle synthesis process and a modified nanoparticle functional-coating process. As used herein reactive-silicone means a silicone that includes either terminal (end) or pendent (side) functional groups. These functional groups may include epoxy/glycidal, vinyl, acrylate, hydride (SiH), and silanol (SiOH). Reactive means that these groups can be used for cross linking of the silicone molecules to achieve polymerization, to increase silicone strength and also provide polarity. Non reactive silicone means silicone with either no groups or with groups that do not cause cross linking, such as alkyl groups or phenyl groups (used for refractive index modifying).Such non reactive silicone is generally in the form of a flexible fluid which is often thermally stable.

Suitable silicones for use in this invention include both siloxanes and silsesquioxanes which are available in both reactive and non reactive forms. Commercially product catalogs list both silioxanes and silsesquioxanes as silicones. Silsesquioxanes have a chemical composition (RSiO1.5) that is a hybrid intermediate between silica (SiO2) and siloxane (R2SiO), where R is an organic group. Silsequioxanes' nanoscopic size and its relationship to polymer dimensions leads to enhancements in the physical properties of polymers incorporating silsesquioxane segments due to its ability to control the motions of the chains.

We have found that the photodegradation characteristics at intensity levels encountered in proximity of green-emitting or blue-emitting LED chip, are not sufficient to meet the reliability requirement of greater than 65% lumen maintenance under 1000 hours of room temperature operation. Thus, we have developed compositionally modified nanoparticles (using Group II elements added during nanoparticle synthesis process or functional-group coating process) to enhance the photodegradation resistance of the nanocomposite Ceramers. Additionally, we have also developed compositionally modified nanoparticles (using Group II elements added during nanoparticle synthesis process or functional-group coating process) that have an outer shell-coating of a larger energy bandgap material (such as Aluminum Oxide or Silicon Oxide), between the nanoparticle and the coupling/dispersing agent coating, which specifically enables a Silicone matrix based nanocomposite Ceramer. An optically transparent Silicone matrix based nanocomposite Ceramer is achieved if the nanoparticles are compositionally modified nanoparticles and the nanoparticles have an outer shell-coating of a larger energy bandgap material ( Silicon Oxide), between the nanoparticle and the coupling/dispersing agent coating.

We have discovered that the loss of LED lamp lumen output due to thermal degradation of the nanocomposite Ceramer at 100C or higher temperatures (required for 1000 hours storage reliability test) is considerably reduced. Thus the present compositionally modified nanocomposite Ceramer exhibits enhanced photothermal degradation resistance. Further, the Silicone matrix based modified nanocomposite Ceramer exhibits enhanced photothermal degradation resistance, compared to the Epoxy matrix based modified nanocomposite Ceramer.

### BRIEF DESCRIPTION OF THE DRAWINGS

For a better understanding of the invention, reference is made to the following drawings which are to be taken in conjunction with the detailed description to follow in which:

FIG. 1 compares the lumen-maintenance characteristics of Epoxy matrix based nanocomposite HRI encapsulants based on the present compositionally modified nanoparticles and conventional nanoparticles. The nanocomposite HRI with compositionally modified nanoparticles exhibits >300× higher duration for 90% Lumen-Maintenance.

FIG. 2 shows the lumen-maintenance characteristics of the present Epoxy matrix based HRI nanocomposite encapsulant in a low-power LED lamp emitting at 525 nm and present Epoxy matrix based HRI nanocomposite encapsulant in a 460 nm chip-based low-power White-LED lamp.

FIG. 3 shows the lumen-maintenance characteristics of the present Silicone matrix based HRI nanocomposite encapsulant in a 460 nm high-efficiency chip-based low-power Blue-LED lamp.

### DESCRIPTION OF THE PREFERRED EMBODIMENTS

The present invention is directed to the manufacture and use of treated nanoparticles coated with an organic functional group that are dispersed in an Epoxy resin or Silicone polymer, exhibiting RI˜1.7 or greater with a low value of optical absorption coefficient α<0.5 cm−1 at 525 nm. The HRI encapsulant can achieve a layer thickness on the order of several mm without exhibiting cracking when annealed at a temperature between 80C to 100C for several hours during curing and over 1000 hours at 100C during high-temperature storage reliability tests. This is in contrast to the optical nanocomposites reported in literature, that have (post-cure) crack-free layer thicknesses on the order of 0.01 mm with α>1 cm−1, and hence cannot be integrated in LED lamps, where the LED chip thickness is at least 0.1 mm.

The present invention is also directed to the manufacture and use of compositionally modified TiO₂ nanoparticles which impart a greater photodegradation resistance (>300×) at 525 nm and 460 nm to the HRI encapsulant, as compared to the conventional TiO₂ nanoparticles used in HRI encapsulants. Compositionally modified TiO₂ nanoparticles that have Group II atoms/ions present either inside the nanoparticle (bulk-doping) or on surface of the nanoparticle (surface-doping or surface-coating) As it is not known whether the “doping” lies on the surface or throughout the nanoparticles the particles herein will be referred to as “treated”. The Group II atoms on the surface may be present in the form of compounds such as oxide or hydroxide (for example MgO islands at the concentrations of Mg discussed below). Additionally, the compositionally modified nanoparticles (using Group II elements added during nanoparticle synthesis process or functional-group coating process) have an outer shell-coating of a larger energy bandgap material (such as Aluminum Oxide or Silicon Oxide), between the nanoparticle and the coupling/dispersing agent coating, which specifically enables a Silicone matrix based HRI nanocomposite. As used herein Silicon Oxide refers generally to SiOx; i.e SiO or SiO₂ as it is difficult to determine which oxide is present in the nano size range.

Nanoparticles of other materials (Oxides, Nitrides and perhaps Sulfides) with high RI and Energy Bandgap larger than that corresponding to LED emission wavelength, may be useable as well but, nanoparticles of Sulfides, Selenides and Tellurides ie. Chalcogenides are notorious for being susceptible to photochemical degradation ( and may require an outer shell-coating of a larger energy bandgap material such as Aluminum Oxide or Silicon Oxide, between the nanoparticle and the coupling/dispersing agent coating). Similarly, the high RI (RI˜2 or greater) nanoparticles of Oxides and Nitrides may require an outer shell-coating of a larger energy bandgap material such as Aluminum Oxide or Silicon Oxide, between the nanoparticle and the coupling/dispersing agent coating, in order to particularly achieve silicone based optically transparent nanocomposites. The nanoparticles used herein are generally less than 100 nm in average diameter (primary particle size) and preferably less than 40 nm and more preferably less than 25 nm, so that they are non light scattering (i.e “invisible” to visible light wavelengths) with a refractive index greater than 2.0 to 2.2 and a band gap higher than 2.7 eV so that they have negligible blue absorption. Other than titanium dioxide (TiO₂),which has an refractive index of 2.5, suitable candidates include: zirconium oxide (ZrO₂), cerium oxide (CeO₂), bismuth oxide (Bi₂O₃), zinc oxide (ZnO), gallium nitride (GaN) and silicon carbide (SiC).

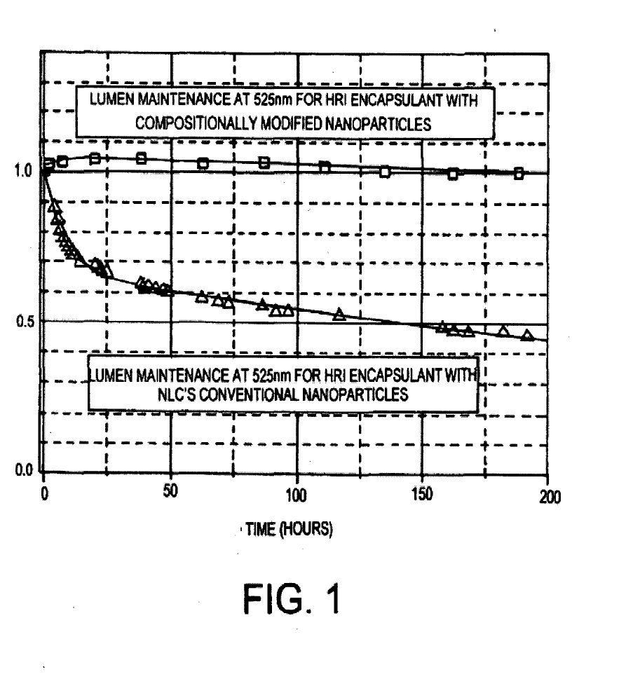

FIG. 1 compares the lumen-maintenance characteristics of Epoxy matrix based nanocomposite HRI encapsulants based on NLC's compositionally modified TiO₂ nanoparticles and NLC's conventional TiO₂ nanoparticles and the 90% lumen-maintenance values are 1000 Hours and <3 Hours, respectively, in a 525 nm emitting low-power LED lamp. The greater photodegradation resistance is believed to be due to a combination of decreased optical absorption at 525 nm as observed in the UV-Visible reflectance spectra from the two TiO2 nanoparticle samples and a decrease in the recombination lifetime of photogenerated electron-hole pairs. A combination of the two effects suppresses the photogenerated carrier concentration available for inducing reactions on the surface of the nanoparticles that are known to result in the optical darkening of nanocomposites.

The lumen-maintenance characteristics of HRI based on compositionally modified TiO₂ nanoparticle with Group II containing compound incorporated in the reactants during growth of the nanoparticle, or with Group II containing compound incorporated in the reactants during coating of the nanoparticle with the organic functional-group, is very similar for the same value of Group II to TiO₂ molar ratio.

Incorporating the Group II containing compound in the reactants during the growth of the nanoparticles, enables a more reproducible and higher transparency HRI with increasing Group II concentration, compared to Group II containing compounds incorporated in the reactants during coating of the nanoparticle with the organic functional-group This is believed to be due to the other chemical species from the Group II containing compound disrupting the functional-coating process of the nanoparticles, by changing the pH of the solution at higher Group II containing compound concentrations. Suitable group II elements for incorporation in the nanoparticles include, by way of example: calcium, strontium, zinc, barium, beryllium and magnesium. It has been found that the lower molecular weight group II elements. i.e. beryllium and magnesium, have a greater solubility and a better loading factor in TiO₂ nanoparticles. However, beryllium has well known toxicity issues and thus magnesium is preferred.

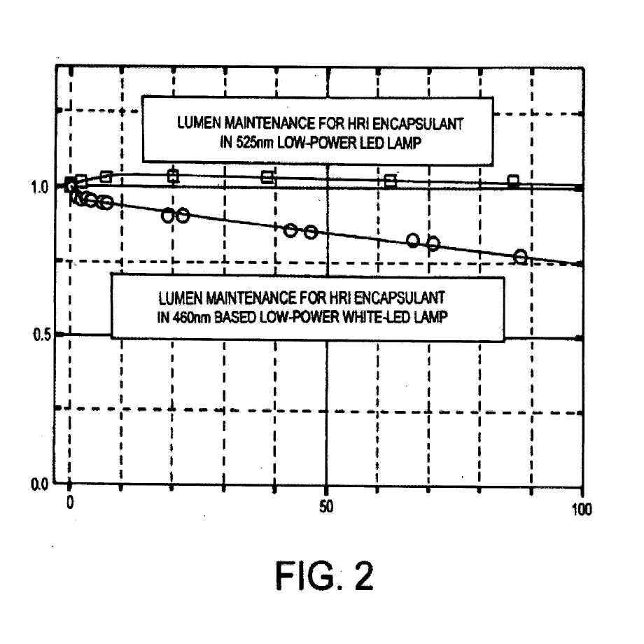

FIG. 2 shows the lumen-maintenance characteristics of our present Epoxy matrix based HRI encapsulant based low-power LED lamp emitting at 525 nm and present Epoxy matrix based HRI encapsulant based low-power White-LED lamp with a 460 nm chip. The present Epoxy matrix based HRI encapsulant 525 nm emitting low-power LED lamps exhibit 90% lumen-maintenance over 1000 Hours. This is in contrast to the 20 Hours for 90% lumen-maintenance under similar conditions for 460 nm based low-power White-LED lamps, due to at present, higher optical absorption by the TiO2 nanoparticle at 460 nm compared to 525 nm. The chemical reactivity of the Epoxy matrix, likely results in the formation of optically absorbing chromophores due to photocatalysis induced by the nanoparticles.

It should be noted, that the lumen-maintenance at 460 nm for the compositionally modified TiO₂ nanoparticle based, Epoxy matrix based HRI, is still better than that of the conventional TiO₂ nanoparticles based, Epoxy matrix based HRI at 525 nm (20 Hrs. vs <3 Hrs. for 90% lumen-maintenance). Conventional TiO₂ nanoparticle based, Epoxy matrix based HRI would exhibit 90% lumen-maintenance for less than 5 minutes at 460 nm. HRI based 525 nm Top LED SMD lamps exhibit ˜25% enhancement in LEE and thus WPE and Optical Power output.

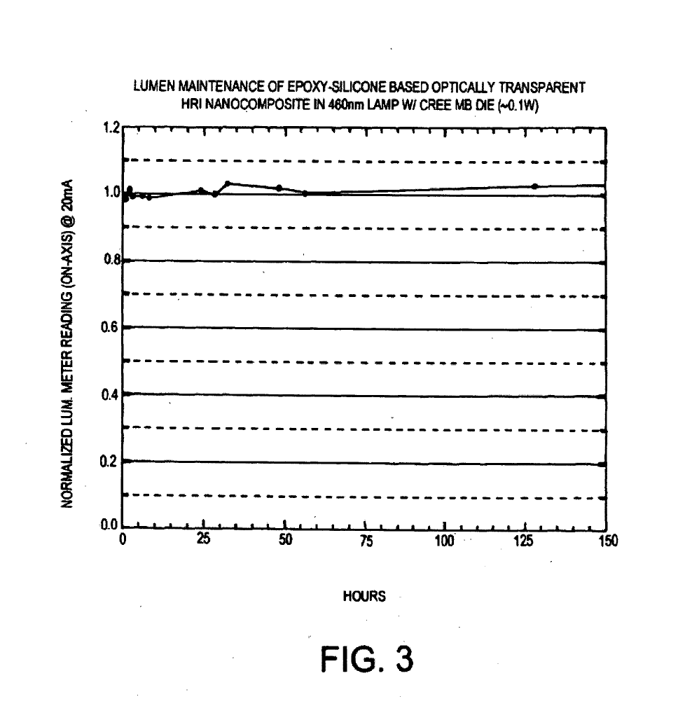

FIG. 3 shows the lumen-maintenance characteristics of our present Silicone matrix based HRI encapsulant based low-power Blue-LED lamp with a 460 nm high-efficiency chip. The present Silicone matrix based HRI encapsulant 460 nm emitting low-power LED lamps exhibit greater than 95% lumen-maintenance over 1000 Hours .The figure shows data for the initial 150 Hours. This is in contrast to less than 1 Hour for 90% lumen-maintenance under similar conditions for our present Epoxy matrix based HRI encapsulant based low-power Blue-LED lamp with a 460 nm high-efficiency chip. The chemical inertness of the Silicone matrix, compared to the Epoxy matrix, likely prevents the formation of optically absorbing chromophores in the nanocomposite. As stated earlier, conventional TiO₂ nanoparticle based, Epoxy matrix based HRI would exhibit 90% lumen-maintenance for less than 5 minutes at 460 nm.

The present Silicone matrix based HRI encapsulant 525 nm emitting low-power LED lamps also exhibit greater than 95% lumen-maintenance over 1000 Hours.

It should be noted that conventional TiO₂ nanoparticles do not yield an optically transparent Silicone matrix based nanocomposite, despite an outer shell-coating of a larger energy bandgap material (such as Aluminum Oxide or Silicon Oxide), between the nanoparticle and the coupling/dispersing agent coating. An optically transparent Silicone matrix based nanocomposite HRI encapsulant is achieved if: the nanoparticles are compositionally modified nanoparticles AND the nanoparticles have an outer shell-coating of a larger energy bandgap material (Silicon Oxide), between the nanoparticle and the coupling/dispersing agent coating.

It should also be noted that the 460 nm chip used in the Blue-LED lamp in FIG. 3 has a higher efficiency than the corresponding 460 nm chip used for the White-LED lamp in FIG. 2. Thus, the HRI encapsulant in FIG. 3 was subjected to higher 460 nm light intensity.

HRI based White-LED lamps with YAG:Ce Phosphor exhibit higher brightness (ie. Candella output) when measured over a wide range of angles (ie higher total Optical Power when integrated over all solid-angles and hence higher Luminous Efficacy, as confirmed by an integrating sphere measurement). The HRI based lamps exhibit at least 40% higher Optical Power compared to the Conventional encapsulant based lamps, for similar color of White-light emission.

Manufacture of TiO₂ Particles Treated with Magnesium

In order to produce a typical batch of 10 gm of TiO₂ Particles, we take four glass vials each containing 19 gm of TBT (Titanium (IV) Butoxide) from Alfa (99%) and 3.5 gm of Glacial Acetic Acid from Aldrich. Each vial is vortexed for 2-3 minutes to provide a homogeneous solution. These vials are placed in a high-pressure reactor from Parr Instrument. For magnesium treated samples, magnesium salt is dissolved in the acetic acid first and then the TBT is added to it. 60 ml of Butanol is placed outside the vials in the reactor, which is one of the byproduct in the reaction. If the Butanol is not placed outside the vials in the reactor, the TiO₂ particles come out dry, possibly with hard-agglomerate size distribution such that it is not possible to coat them and obtain an optically non-scattering dispersion. However, external Butanol may not be necessary when a larger quantity of the initial reactants is used. Such as for example, 100 gm of TBT and correspondingly scaled quantities of other reactants).The reactor is closed and purged with nitrogen for 2 minutes to remove the air. The reactor is then filled with an initial pressure of 200 to 300-psi nitrogen and is heated to 210 to 230° C. for 2 to 5 hrs. However, a lower initial pressure of nitrogen may be used when a larger quantity of the initial reactants is used. Such as for example, 100 gm of TBT and correspondingly scaled quantities of other reactants. The particles, when they come out of the reactor are washed with Hexane/Heptane to remove byproducts formed during the reaction. After centrifugation the particles are suspended in 2-Butanone are then ready for coating.

In order to produce “Example A” herein which is 4 wt % Mg treated TiO2—the quantities of reactants are 10 gm TBT, 584 mg Magnesium Acetate (99.999% Aldrich), and 3.5 gm Glacial Acetic Acid. In order to produce “Example B” herein which is 4% Mg Treated TiO2—the quantities of reactants are 10 gm TBT, 584 mg Magnesium Acetate (99.999% Aldrich) and 3.5 gm Glacial Acetic Acid. The Mg treated TiO2 particles produced herein are less than 25 nm in their largest dimension, which ensures that the particles will be optically “invisible” (non scattering) since they are considerably smaller than the wavelengths of light emitted by the LED which also permits a high “loading factor” of particles in the encapsulant. Furthermore, even if the individual treated TiO2 particles agglomerate, such agglomerated groups are quite small (30-35 nm or smaller) as the finished encapsulant is optically non scattering to the extent that is required to obtain an enhancement of the optical power and wall plug efficiency of an LED lamp incorporating the encapsulant.

In order to produce Mg treated TiO₂ nanoparticles with an outer shell-coating of a larger energy bandgap material such as Aluminum Oxide or Silicon Oxide (ie. a Core-Shell nanoparticle with a Mg treated TiO₂ “Core” and an Aluminum Oxide or Silicon Oxide “Shell”), a two-stage growth process is utilized—The high-pressure reactor containing the above described reactants is heated to 210 to 230° C. for 2 to 5 hrs to enable the Mg treated TiO₂ nanoparticle growth, and then cooled down to room temperature. The reactor is opened and Aluminum Butoxide or Silicon Butoxide is added and uniformly stirred/mixed into each vial containing the TiO₂ nanoparticles. The quantity of Aluminum Butoxide or Silicon Butoxide added into each vial was approximately between 20 to 40 wt % of the initial quantity of TBT in each vial at start. Optionally, a quantity of water between 0.5 to 2 wt % of the initial quantity of TBT may be added in each vial at the start to improve the quality of the outer shell coating. The reactor is closed and purged with nitrogen for 2 minutes to remove the air. The reactor is then refilled with an initial pressure of 200 to 300-psi nitrogen and is reheated to 210 to 230° C. for 2 to 5 hrs (However, a lower initial pressure of nitrogen may be used when a larger quantity of the initial reactants is used. Such as for example, 100 gm of TBT and correspondingly scaled quantities of other reactants). The Mg treated Core-Shell nanoparticles, when they come out of the reactor are washed with Hexane/Heptane to remove byproducts formed during the reaction. After centrifugation the particles are suspended in 2-Butanone, and are then ready for coating. Alternately, Heptane-Alcohol or Toluene-Alcohol mixture may be used as a solvent instead of 2 -Butanone. The outer shell-coating of a larger energy bandgap material provides improved performance.

Coating of Treated TiO2 with Coupling/Dispersing Agent ps Coating with a Relatively Polar Methacrylate Functional-Group

In a typical batch for coating of treated TiO2 particles, TiO₂ particles from two vials are combined, which is about 5 gms in 80 ml 2-Butanone and are sonicated for between one to three hours. Butanone which is an aprotoic solvent, is used in this example, an aqueous solvent such as an alcohol-water mixture may be used. Add 250 uL water and thereafter 1.76 ml of coupling/dispersing agent (Methacryloxypropyltrimethoxysilane). Alternately, the quantity of both water and coupling/dispersing agent may be scaled by a factor between 0.75 to 4.125 ul of Acetic Acid pH 3-4 was added and the solution becomes transparent thereafter. Alternatively, a basic pH attained using addition of Ammonium Hydroxide for example, may be used. Alternately, neither an acid or base is used. This solution is stirred for 2-80 hrs at 60-100° C. Alternately, room temperature may be used. The solvent is removed from the solution using a rotovap at 70-80° C. Coated TiO₂ particles are then washed with heptane to remove free coupling/dispersing agent. Washed particles are dispersed in 2-butanone or Toluene-Alcohol mixture and the total volume is 50 ml.

In addition to Methacryloxypropyltrimethoxysilane other suitable agents for coupling/dispersing the treated TiO₂ to an optically clear epoxy or optically clear reactive-silicone may be used, such coupling/dispersing agents include; Alkyl-terminated AlkoxySilanes (such as for example, PropylTrimethoxySilane, ButylTrimethoxySilane, OctylTrimethoxysilane, DodecylTriethoxysilane) , Phenyl-terminated AlkoxySilane, Allyl-terminated AlkoxySilane, Vinyl-terminated AlkoxySilane, Octenyl-terminated AlkoxySilane, Glycidyl-terminated AlkoxySilane and HexaMethylDiSilazane. The above described process is also used for the Mg treated Core-Shell nanoparticles with a Mg treated TiO₂ “Core” and an Aluminum Oxide or Silicon Oxide “Shell”.

Coating with a Relatively Non-polar Alkyl Functional-group

In a typical batch for non-polar Alkyl functional-group coating of Mg treated Core-Shell nanoparticles with a Mg treated TiO₂ “Core” and an Aluminum Oxide or Silicon Oxide “Shell”, TiO₂ particles from two vials are combined, which is about 5 gms in 80 ml 2-Butanone and are sonicated for between one to three hours. Butanone which is an aprotoic solvent, is used in this example, an aqueous solvent such as an alcohol-water mixture may be used. Alternately, Heptane-Alcohol or Toluene-Alcohol mixture may be used as a solvent instead of 2-Butanone. Add 250 uL water and thereafter 1.76 ml of coupling/dispersing agent (Octyltrimethoxysilane). Alternately, the quantity of both water and coupling/dispersing agent may be scaled by a factor between 0.75 to 4.125 ul of Acetic Acid pH 3-4 was added and the solution remains opaque in 2-Butanone, but turns translucent in Heptane-Alcohol or Toluene-Alcohol mixture as solvent. Alternatively, a basic pH attained using addition of Ammonium Hydroxide for example, may be used. Alternately, neither an acid or base is used. This solution is stirred for 12 to 80 hrs at 60-100° C. The solvent is removed from the solution using a rotovap at 70-80° C. Coated TiO₂ particles are then washed with methanol to remove free coupling/dispersing agent. Washed particles are dispersed in Toluene and the total volume is 50 ml.

The non-polar Alkyl functional-group coated particles dispersed in Toluene may be further subjected to a secondary-coating with HexaMethylDiSilazane (HMDZ). Addition of HMDZ to the dispersion is followed by refluxing under stirring for 12 to 80 hrs. The solvent is removed from the solution using a rotovap at 70-80° C. The secondary-coated TiO₂ particles are then washed with methanol to remove free coupling/dispersing agent. Washed particles are then re-dispersed in Toluene. Alternately, the unreacted excess HMDZ may be removed by using a rotovap or vacuum-drying, prior to re-dispersion. The HMDZ secondary-coating further enhances the non-polar nature of the coated-particles and also enhances the stability/shelf-life of the dried coated-particles, with respect to their ability to be re-dispersed in a solvent.

The choice of polar or non-polar functional-group coatings generally depends on the encapsulants to be used, epoxies are generally compatible with polar functional groups while silicones are generally compatible with non-polar functional groups. Epoxy is reactive and tends to yellow more easily and works best with lower intensity LEDs, however it is generally much less expensive than silicones and is stronger.

High Refractive Index Encapsulants

### EXAMPLE A

### HRI Epoxy Encapsulant From 4% Mg Treated Coated TiO₂

The 4% Mg treated Methacrylate functional-group coated TiO₂ (1.00 g) in (10 ml) 2-butanone was mixed with epoxy (Loctite OS 4000 part A) (0.58 g) in a round bottom flask and the mixture was refluxed for 3 hours. Upon cooling, the solution was concentrated on a rotary evaporator under vacuum at 50° C. until the volume was reduced to (5 ml).Thereafter 4-methyl-2-pentanone (1 ml) (Aldrich Chemical Co ) was added to the mixture and transferred to a centrifuge tube and centrifuged at 3000 rpm for 15 minutes. After centrifugation, the liquid was decanted and concentrated on a rotary evaporator to obtain the desired consistency of HRI epoxy encapsulant.

### EXAMPLE B

### HRI Epoxy-Terminated Reactive-Silicone Encapsulant From 4% Mg Treated Coated TiO₂

The 4% Mg treated Octyl functional-group coated TiO₂ (1.00 g) in (10 ml) Toluene was mixed with Epoxy-Terminated Silicone (0.5 g) in a round bottom flask. The solution was concentrated on a rotary evaporator under vacuum at 50° C. until the volume was reduced to obtain the desired consistency of HRI Epoxy-Terminated Silicone encapsulant. Alternately, the solution may be concentrated on a rotary evaporator under vacuum at room-temperature. Alternately, Octenyl functional-group coated TiO₂ was also used in the above example.

EpoxyPropoxyPropyl-Terminated DiMethylSiloxane (or EpoxyPropoxyPropyl-Terminated DiPhenylDiMethylSiloxane or EpoxyPropoxyPropyl-Terminated PolyPhenylMethylSiloxane), which is a one of the constituents of Silicone-based elastomers for optical applications, is used to obtain a Epoxy-Terminated Silicone-based HRI encapsulant. Similarly, EpoxyPropoxyPropyl-Terminated Siloxane may be mixed with Vinyl-Terminated Siloxane . When mixing the Epoxy-Terminated and Vinyl-Terminated Silicones as the matrix, the Silicone chain-length or the number of Siloxane repeat-units that is described by Degree of Polymerization (DP), may have to be less than DP˜70.

### EXAMPLE C

### HRI Vinyl-Terminated Reactive-Silicone Encapsulant From Mg Treated Coated TiO₂

The 4% Mg treated Allyl functional-group coated TiO2 (1.00 g) in (10 ml) 1-butanol was mixed with Vinyl-Terminated Silicone (0.5 g) in a round bottom flask and the solution was concentrated on a rotary evaporator under vacuum at 50oC until the volume was reduced to obtain the desired consistency of HRI Vinyl-Terminated Silicone encapsulant. Alternately, the solution may be concentrated on a rotary evaporator. under vacuum at room-temperature. Vinyl-Terminated PolyPhenylMethylSiloxane (or Vinyl-Terminated DiPhenylDiMethylSiloxane or Vinyl-Terminated DiMethylSiloxane) which is a primary constituent of Silicone-based elastomers for optical applications, is used to obtain a Vinyl-Terminated Silicone-based HRI encapsulant.

### EXAMPLE D

### HRI Vinyl-Terminated Blend Reactive-Silicone Encapsulant From Mg Treated Coated TiO₂

The 4% Mg treated Octyl functional-group coated TiO₂ (1.00 g) in (10 ml) Toluene was mixed with a Reactive-Silicone (0.5 g) blend (in 1:1 ratio by weight) comprised of EpoxyPropoxyPropyl-Terminated DiMethylSiloxane (RI˜1.42) and Vinyl-Terminated PhenylMethyl Siloxane (RI˜1.53) in a round bottom flask and the solution was concentrated on a rotary evaporator under vacuum at 50° C. until the volume was reduced to obtain the desired consistency of HRI Vinyl-Terminated Silicone encapsulant. Alternately, the solution may be concentrated on a rotary evaporator under vacuum at room-temperature. The HRI encapsulant exhibited RI˜1.74 at 600 nm wavelength and a correspondingly higher value at 450 nm wavelength, after removal of solvent.

### EXAMPLE E

### HRI Vinyl-Terminated and Hydride-Terminated Blend Reactive-Silicone Encapsulant From Mg Treated Coated TiO₂

The 4%Mg treated Octyl functional-group coated TiO₂ (1.00 g) in (10 ml) Toluene was mixed with a Reactive-Silicone (0.5 g) blend (with ratio ranging from 2:1:1 to 0:1:1 by weight) comprised of EpoxyPropoxyPropyl-Terminated DiMethylSiloxane (RI˜1.42), Vinyl-Terminated PhenylMethyl Siloxane (RI˜1.53) and Hydride-Terminated PhenylMethyl Siloxane (RI˜1.5), respectively, in a round bottom flask and the solution was concentrated on a rotary evaporator under vacuum at 50° C. until the volume was reduced to obtain the desired consistency of HRI Vinyl-Terminated and Hydride-Terminated Blend Silicone encapsulant. Alternately, the solution may be concentrated on a rotary evaporator under vacuum at room-temperature. Alternately, Octenyl functional-group coated TiO₂ and Allyl functional-group coated TiO₂ was also used in the above example. The HRI encapsulant exhibited RI˜1.7 to 1.74 at 600 nm wavelength and a correspondingly higher value at 450 nm wavelength, after removal of solvent.

### EXAMPLE F

### HRI Non-Reactive Silicone (Silicone Fluid) Encapsulant From Mg Treated Coated TiO₂

The 4% Mg treated Octyl functional-group coated TiO₂ (1.00 g) in (10 ml) Toluene was mixed with a Non-Reactive Silicone fluid(0.5 g) TetraPhenylTetraMethylTriSiloxane (RI˜1.55) in a round bottom flask and the solution was concentrated on a rotary evaporator under vacuum at 50° C. until the volume was reduced to obtain the desired consistency of HRI Non-Reactive Silicone (Silicone Fluid) encapsulant. Alternately, the solution may be concentrated on a rotary evaporator under vacuum at room-temperature. The HRI encapsulant exhibited RI˜1.74 at 600 nm wavelength and RI˜1.78 at 450 nm wavelength. Alternately, other Non-Reactive Silicone fluids such as TriPhenylPentaMethylTriSiloxane and PentaPhenylTriMethylTriSiloxane were also used in the above example. Alternately, Octenyl functional-group coated TiO₂ was also used in the above example.

Dispensing In Monochrome & White-Light Top LED SMD Lamps and 5mm Bullet LED Lamps

The present HRI encapsulant may be used with a wide variety of lamp structures, particularly suitable photonic structures are found in U.S. Pat. No. 6,734,465 entitled “Nanocrystalline Based Phosphors And Photonic Structures For Solid State Lighting” issued May, 4 2004, PCT Application No. PCT/US2004/029201 and US Published patent application No. 2006/0255353 the disclosures of which are hereby incorporated by reference. Taking into account ˜30% to 60% volume shrinkage, due to evaporation of the pentanone or toluene solvent, between 6 to 7 micro-liters of the above mix is dispensed in the Top-Emitting SMD monochrome lamps, or preferably between 0.5 to 2 micro-liters of the above mix to achieve a semi-hemispherical HRI form-factor encapsulating the LED chip. Approximately 1 micro-liter or less of the above mix is dispensed in the reflective-cavity (reflector-cup) of the 5 mm lamps. The dispensed volume and rheology of the mix is typically adjusted to achieve a particular shape of the HRI-Air interface after curing. Typically the curing is done at room temperature for ˜24 Hrs or can be accelerated at 80° C. for few hours. Please note that very often, no hardener (i.e. Part B of the Epoxy or Silicone) is added as a curing agent since the surface-coating on the TiO₂ may serve as a curing agent. The HRI may then be over-encapsulated after curing by a conventional encapsulant in accordance with the teachings of PCT Application No. PCT/US2004/029201 and US Published patent application No. 2006/0255353 the disclosures of which are hereby incorporated by reference.

For the White-Light lamps, ˜20 mg to 100 mg of commercial YAG:Ce bulk-phosphor is added per ˜1 gm of HRI mix (without including solvent weight). The phosphor loading (mg YAG:Ce per gm of HRI volume) may be varied to obtain the desired chromaticity-coordinates and depends on the details of the LED chip and package geometry. Similar volume shrinkage as encountered in the monochrome lamps, is accounted for during dispensing, and similar form-factor for the HRI plus phosphor mix (as that in monochrome lamps) is preferred.

Dispensing in High-Power LED lamps or even the Low-Power SMD lamps uses the strategy of only partially filling the reflector cup with the HRI, by implementing a semi-hemispherical shaped HRI “blob” encapsulating the LED chip. Remainder of the reflector cup volume is filled with a conventional encapsulant (with RI˜1.5), and if necessary a pre-molded lens with RI˜1.5 may be attached. The total HRI encapsulant volume is on the order of ˜1 to 2 micro-liters, which is considerably lower than the ˜10 to 20 microliter HRI volume required to fill the entire reflector cup and the remaining lamp volume of a High-Power lamp. This HRI “blob” strategy requires a relatively smaller volume of the HRI mix on the order of 2 to 4 micro-liters at the most. Similar strategy of filling only the reflector cup is used for the Bullet-shaped 5 mm LED lamps. However, the dispensed volume is 1 micro-liters with the HRI volume after curing being less than 1 micro-liter (compared to greater than 100 micro-liter volume for the Bullet-shaped 5 mm lens).

Integration in Polymer-Based Photonic Waveguides

The present HRI nanocomposite may be used in a variety of polymer-based photonic waveguide structures as the higher refractive-index photon-confining core/guiding region. Polymer-based photonic waveguide structures for Planar Lightwave Circuits (PLCs) applications in photonic-communication or optical interconnect are known in the art. The wavelength of photons transmitted in the waveguides for these applications ranges between 780 nm to 1600 nm (longer than the visible LED wavelengths), and the intensity levels in the core/guiding region could range in the 1 to several-100 kilowatt/cm². Thus, the enhanced photothermal stability of the present HRI nanocomposite (in addition to its high RI) is expected to be of an advantage in this application.

Polymer waveguides offer the advantage of lower fabrication costs due to use of spin-coating techniques for implementation of the polymer based cladding and core/guiding layers in the waveguides (rather than standard Silicon-processing techniques such as CVD and thermal-annealing, that require higher thermal-budgets and fabrication-cost). Typically, polymer waveguides require processing temperatures less than 150 degrees C., whilst other materials based waveguides require processing temperatures in excess of 300 degrees C.

Conventionally, Silicone polymers or other polymers with refractive indices in the range of 1.4 to 1.5 are used for fabricating the cladding and core/guiding regions via spin-coating, photolithographic patterning, and etching in some cases. Typically, a RI˜1.45 Silicone polymer is used for the cladding layers and a higher RI˜1.5 Silicone polymer is used for the core/guiding region of the waveguide. The thicknesses of the cladding and core/guiding regions are typically on the order of 1 to few 10s of microns and the core/guiding region typically is a ridge (surrounded by cladding) with a width on the order of 5 to few 10s of microns. RI difference of about 2% between the cladding and core/guiding enables fabrication of waveguides with a bend-radius of ˜2 mm, without loss of light confinement in the core/guiding (or light leakage from the waveguide). Increasing the packing-density of the waveguides (for higher functionality per unit area on wafer, or alternately reduced cost of optical component for a particular functionality) requires a further reduction in bend-radius which can only be enabled by a higher difference in RI between the cladding and core/guiding regions. RI difference of 20%, between RI˜1.45 cladding and RI˜1.74 core/guiding enables a waveguide bend-radius of 0.1 mm—Thereby significantly improving either the functionality per component or the cost per component.

Compared to thin-film HRI materials such as SiliconOxyNitride, other mixed-Oxides and ORMOCER—The present Silicone-based HRI nanocomposite require processing temperatures less than 150 degress C. (or even less than 100 degrees C.), compared to processing temperatures in excess of 300C for the alternatives (and also thicker films with higher RI contrast compared to SiliconOxyNitride).

The Silicone-based HRI nanocomposite mix is spin-coated on a cladding layer comprised of either Silicon dioxide (grown or deposited) on a Silicon wafer, or a RI˜1.4 to 1.5 conventional Silicone polymer layer spin-coated on the wafer. The viscosity of the HRI nanocomposite mix is adjusted via controlling the solvent concentration, to obtain a uniform ˜10 micron thick layer on the wafer. Depending on the optical design for the waveguide, layers in the 1 to 10 micron thickness could be obtained by a combination of thinning the HRI mix and increasing the spin-speed. Thicker layers could be obtained by multiple spin-coating steps. The HRI nanocomposite layer could be patterned to obtain a ˜10 micron wide ridge, using imprint lithography or photolithography/photopatterning. The HRI nanocomposite ridge is then covered with a ˜10 micron or thicker RI˜1.4 to 1.5 conventional Silicone polymer layer, to form the upper cladding layer.

Integration as a Visible Light Optical Waveguide

The present HRI nanocomposite may be used in a variety of visible light waveguiding structures as the higher refractive-index photon-confining core/guiding region. This may or may not be in conjunction with its use as an optical adhesive. Back Lighting Modules (BLM) for visible displays are known in the art. The lightguide plate in the BLM and the glass-substrate of the TFT-LCD have a similar RI˜1.5, and may be optically coupled using an optical adhesive layer. The use of a HRI nanocomposite instead of a conventional RI˜1.5 coupling layer would result in lateral waveguiding of light (exiting the BLM lightguide plate) in the HRI nanocomposite, since both the BLM lightguide plate and the TFT-LCD glass-substrate with relatively lower RI serve as the cladding layers. Relatively higher lateral waveguiding in the coupling layer is expected to enhance the uniformity of illumination provided by the BLM into the TFT-LCD. This may be manifested in a BLM design with wider spacing between the LED lamps resulting in fewer LED lamps per BLM, thus consequently lowering the BLM cost since LED lamps constitute the most significant cost of materials/components in the BLM. A combination of HRI nanocomposite optical properties such as RI and optical scattering coefficient, and the details of the optical design/structure of the lightguide plate/BLM would determine the extent of lateral waveguiding versus outcoupling of light into the TFT-LCD. Optical scattering coefficient of the HRI nanocomposite can be modified by altering the nanoparticle size distribution to include larger-sized nanoparticles that contribute to optical scattering (but not to RI or optical absorption) in the nanocomposite. The wavelength of photons transmitted in the waveguide for these applications ranges between 450 nm to 650 nm, and the intensity levels in the core/guiding region would be similar to or typically less than those encountered by an encapsulant inside a LED package. Thus, the enhanced photothermal stability of the present HRI nanocomposite (in addition to its high RI) is expected to be of an advantage in this application.

Integration as a High-Voltage Electrical Insulator or Encapsulant

The present HRI nanocomposite may be used in a variety of electrical devices, device packages and structures as an electrical insulator or encapsulant with higher electrical breakdown field strength than silicone or polymeric materials. High-voltage electrical devices are known in the art. Electrical field strength during operation in proximity of these devices and in packages containing these devices exceed the breakdown field strength of air (1.5 Volts/micron), warranting the use of silicone or polymeric materials that have breakdown field strength in the range of 15 to 35 Volts/micron. Although silicone and polymeric insulators and encapsulants have a factor of 10× lower breakdown field strength than deposited dielectric layers such as silicon dioxide or silicon nitride—They can be implemented in thickness exceeding several millimeters in contrast to several tens of microns for the deposited dielectric layers, and are thus capable of withstanding higher operating voltages.

The inventors have discovered that the HRI nanocomposite exhibits a higher breakdown field strength in excess of 80 to 120 Volts/micron (for RI˜1.7), considerably in excess of the breakdown field strength exhibited by silicone and polymeric insulators and encapsulants. In semiconductor power devices particularly for those based on Wide-Bandgap semiconducting materials such as GaN and SiC (microwave and high-voltage devices), the electric field strength inside the insulation layers in close proximity approaches that inside the semiconducting material, which could be in the range of 100 Volts/micron. Electric field strength values of this magnitude normally require the use of deposited dielectric layers. But the comparable breakdown field strength of the HRI nanocomposite in conjunction with the ability to spin-coat thin-films in the micron range opens up the possibility of its use as device insulating layers.

The chip/die size of the Wide-Bandgap GaN or SiC devices is considerably reduced compared to a Silicon device operating at the same voltage or power. However, the silicone and polymeric materials that are used for encapsulation are required to have adequate thickness in the package so as to limit the electric field strength below their breakdown field strength value of 15 to 35 Volts/micron—Thus, limiting the extent to which the dimensions of the package size can be reduced, despite the reduction in die size.

The higher breakdown field strength of the HRI nanocomposite in conjunction with its ability to form layers in the micron to several millimeter range thickness—will enable the realization of thinner insulating/encapsulating layers and smaller sized encapsulation dimensions for devices operating at the same electrical voltage values (compared to silicone and polymeric insulators and encapsulants). This would prove to be advantageous with respect to reducing the package form-factor for Widebandgap GaN, SiC or other materials based devices (in addition to Silicon based devices), due to smaller volume of insulator or encapsulant required in the package. Alternately, a higher operating voltage capabilty would be imparted to a device package utilizing the same form-factor, but using the HRI nanocomposite instead of the silicone and polymeric insulator/encapsulant.

It is also anticipated, that the optical transparency of the HRI nanocomposite would prove to be advantageous during dispensing of the insulator/encapsulant within the device package—Particularly, with respect to the alignment of the encapsulant relative to other components in the device package.

The coupling/dispersing agents and the Silicone polymers used in these examples are readily commercially available, and may be purchased by way of example, from Gelest Inc. (Morrisville, Pa.).

The invention has been described with respect to preferred embodiments. However, as those skilled in the art will recognize, modifications and variations in the specific details, quantities and process steps which have been described and illustrated may be resorted to without departing from the spirit and scope of the invention.

1. A high refractive index light path material comprising:
a) TiO₂ nanoparticles having an average primary particle size of less than 40 nm, said TiO₂ nanoparticles being treated with 1 to 5 wt % of a group II element;
b) a coupling/dispersing agent coating the treated TiO₂ nanoparticles;
c) an optically transparent epoxy into which a multiplicity of the coated treated TiO₂ nanoparticles are dispersed.

2. The high refractive index material as claimed in claim 1, wherein the group II element is magnesium.

3. The high refractive index material as claimed in claim 1, wherein the coupling/dispersing agent is Methacryloxypropyltrimethoxysilane

4. The high refractive index material as claimed in claim 1, wherein the material has a refractive index greater than 1.6.

5. The high refractive index material as claimed in claim 1, wherein the material is an encapsulant for a light emitting device and has a refractive index greater than 1.8.

6. The high refractive index material as claimed in claim 1, wherein the TiO₂ nanoparticles have an outer shell-coating of a larger energy bandgap material, between the TiO₂ nanoparticle and the coupling/dispersing agent coating.

7. A reliable high refractive index light path material comprising:
a) TiO₂ nanoparticles having an average primary particle size of less than 40 nm, said TiO₂ nanoparticles being treated with 1 to 5 wt % of a group II element;
b) a coupling/dispersing agent coating the treated TiO₂ nanoparticles;
c) an optically transparent silicone into which a multiplicity of the coated treated TiO₂ nanoparticles are dispersed.

8. The high refractive index material as claimed in claim 7, wherein the group II element is magnesium.

9. The high refractive index material as claimed in claim 7, wherein the coupling/dispersing agent is selected from the group consisting of Octyltrimethoxysilane, Octenyltrimethoxysilane and Allyltrimethoxysilane

10. The high refractive index material as claimed in claim 7, wherein the wherein the light path material comprises an encapsulant for a light emitting device.

11. The high refractive index material as claimed in claim 7, wherein the material has a refractive index greater than 1.6.

12. The high refractive index material as claimed in claim 7, wherein the silicone material comprises reactive silicone

13. The high refractive index material as claimed in claim 12, wherein the reactive silicone material comprises at least one of a siloxane and a silsesquioxane .

14. The high refractive index material as claimed in claim 7, wherein the TiO₂ nanoparticles have an outer shell-coating of a larger energy bandgap material, between the TiO₂ nanoparticle and the coupling/dispersing agent coating.

15. The high refractive index material as claimed in claim 7, wherein the outer shell-coating of a larger energy bandgap material comprises at least one of silicon oxide and aluminum oxide.

16. The high refractive index material as claimed in claim 7, wherein the silicone material comprises non reactive silicone

17. The high refractive index material as claimed in claim 16, wherein the non reactive silicone material comprises at least one of a siloxane and a silsesquioxane .

18. The high refractive index material as claimed in claim 7, wherein the wherein the light path material comprises the light confining core/guiding region of a photonic waveguiding device.

19. The high refractive index material as claimed in claim 7, wherein the wherein the light path material comprises a high electric breakdown field strength encapsulant for an electrical device.

20. The high refractive index material as claimed in claim 7, wherein the high electric breakdown field strength encapsulant has an electric breakdown field strength greater than 80 Volts/micron.

21. A method of making a reliable high refractive index light path material, comprising the steps of:
a) providing a multiplicity of TiO₂ nanoparticles;
a) treating the TiO₂ nanoparticles with a group II element;
b) coating the treated TiO₂ nanoparticles with a coupling/dispersing agent;
c) dispersing the coated treated TiO₂ nanoparticles within an optically transparent silicone so as to form the light path material.

22. The method as claimed in claim 21 further including the step of providing the treated TiO₂ nanoparticles with an outer shell-coating of a larger energy bandgap material, between the treated TiO₂ nanoparticle and the coupling/dispersing agent.

23. The method as claimed in claim 22 wherein the outer shell-coating of a larger energy bandgap material comprises at least one of silicon oxide and aluminum oxide.

23. The method as claimed in claim 21 wherein TiO₂ nanoparticles are simultaneously provided and treated.

24. The method as claimed in claim 21, wherein the group II element is magnesium.

25. The method as claimed in claim 21, wherein the coupling/dispersing agent is selected from the group consisting of Octyltrimethoxysilane, Octenyltrimethoxysilane and Allyltrimethoxysilane.

26. The method as claimed in claim 21, wherein the silicone material comprises reactive silicone

27. The method as claimed in claim 26, wherein the reactive silicone material comprises at least one of a siloxane and a silsesquioxane .

28. The method as claimed in claim 21, wherein the silicone material comprises non reactive silicone.

29. The method as claimed in claim 28, wherein the non reactive silicone material comprises at least one of a siloxane and a silsesquioxane .

30. A refractive index raising composition for addition to light path material comprising:
a) nanoparticles having an average primary particle size of less than 40 nm a refractive index greater than 2 and a band gap higher than 2.7 eV;
b) said nanoparticles including 1 to 5 wt % of a group II element;
c) an outer shell-coating disposed around said nanoparticles of a material having a bandgap higher than that of the nanoparticles; and
d) a coupling/dispersing agent coating the treated nanoparticles.

31. The refractive index raising composition as claimed in claim 30 wherein the nanoparticles comprise at least one of: titanium dioxide (TiO₂), zirconium oxide (ZrO₂), cerium oxide (CeO₂), bismuth oxide (Bi₂O₃), zinc oxide (ZnO), gallium nitride (GaN) and silicon carbide (SiC).

32. The refractive index raising composition as claimed in claim 30 wherein the group II elements included in the nanoparticles comprise at least one of calcium, strontium, zinc, barium, beryllium and magnesium

33. The refractive index raising composition as claimed in claim 30 wherein the outer shell-coating of a larger energy bandgap material comprises at least one of silicon oxide and aluminum oxide.

34. The refractive index raising composition as claimed in claim 30 wherein the coupling/dispersing agent comprises at least one of Octyltrimethoxysilane, Octenyltrimethoxysilane and Allyltrimethoxysilane.
